(19) United States
(12) Patent Application Publication
(10) Pub. No.: US 2010/0052950 A1
(43) Pub. Date: Mar. 4, 2010

(54) Multi-input multi-directional device for computer or electronic device input (keyboard-type device)

(76) Inventor: Stephen Reid Collier, Virginia Beach, VA (US)

Correspondence Address: Stephen R. Collier, 5373 Leicester Ct, Virginia Beach, VA, 23462, US

(21) Appl. No.: 12/202,234

(22) Filed: Aug. 30, 2008

(51) Int. Cl. H03M 11/00

(52) U.S. Cl. 341/22

(57) ABSTRACT

The invention is to enable quick keyboard input for practically any sized device through the use of two primary multi-direction inputs. By pressing two multi-direction inputs, each in a direction, the user enters an alphanumeric character. Existing patents (U.S. Pat. Nos. 6,590,566, 7,171,498, 7,417,566) require larger, slower interfaces or aren't as user friendly.

### BACKGROUND OF THE INVENTION

There have been many solutions created for the input of alphanumeric characters for small devices and still more solutions for keyboard input. For small devices the solutions are often clumsy, using numeric keypads or tiny keys for input. It can be argued that there is no standard device that can meet the requirements of fitting into a small interface and allowing input at the speed of a full keyboard.

### BRIEF SUMMARY OF THE INVENTION

The intention of this invention is to enable quick keyboard input for practically any sized device through the use of two primary multi-direction inputs. By pressing two multi-direction inputs, each in a direction, the user enters an alphanumeric character. With two eight-direction inputs, for example, it is possible to enter any of 64 characters quickly with two simultaneous or sequential movements. Once a user is familiar with the combinations for each character, input can be quite rapid. The small interface of two multi-direction inputs would easily fit onto phones and other small devices.

### DETAILED DESCRIPTION OF THE INVENTION

The primary means of input for the invention are two multi-direction inputs, made from existing devices or as software for a touch screen device or device capable of accepting two multi-direction inputs. Examples of existing devices are video game controller D-pads, analog joysticks, 8-direction digital inputs, iPod wheel, etc.

The functioning of the invention is such that when both multi-direction inputs are moved into non-neutral positions the appropriate character is sent as input to the attached device that the invention serves as a keyboard for. Other optional inputs can serve to increase the total number of characters available for input, such as buttons that serve as the Ctrl, Shift, and Alt keys on a standard keyboard.

When the invention serves as input for a touch screen or similar existing device, it is implemented as software. The software must establish the two base points where the user touches the screen. It then must detect the events where the user moves the touch points in one of the directions. When both touch points are out of the base points and in a non-neutral position, the software will input the appropriate character. Optionally, if the touch points are held in the non-neutral positions the software can repeat the input of the character to the system. When either touch point returns to the neutral position input to the system ceases.

When implemented as hardware existing multi-position devices can be used as inputs. A microprocessor can be used to poll the multi-position devices and optional inputs to determine the position of the inputs and to send events to the system the invention serves as input for. There are many existing systems that would serve as multi-position and other inputs, such as video game controllers or radio controlled vehicle controllers.

The invention differentiates itself from the prior art by providing a new means of inputting text to a system using a very small interface. While the inputs are made from existing devices, the software that responds to the inputs is unique in that it takes the minimal inputs from the user and interprets them as characters sent to the system.

The optional visual display allows the user to see which characters are available for the direction indicated. When one multi-direction input is in a non-neutral position the display for the other input shows which character will be input for each direction. When both multi-direction inputs are in the neutral position the display can show either a range of characters (ex. A-H) or all the characters available for that direction. The optional display can be implemented as software for a touch screen, software for an LCD display, or as hardware display.

Another optional display would be for braille to be displayed in the same way that the optional visual display, using hardware that can form braille characters in place or in addition to the visual display.

The device can also be formed with one or more than two multi-direction inputs. Additional multi-direction inputs would increase the number of characters that can be input when the user has put each input in a non-neutral position. If the invention is created using only one multi-direction input, the state of the first position must be stored in RAM and the second input would be combined with the stored input to be translated into a character input for the system.

The actual arrangement of the characters can be established by a standards body.

### EXAMPLE (NON-LIMITING CASE)

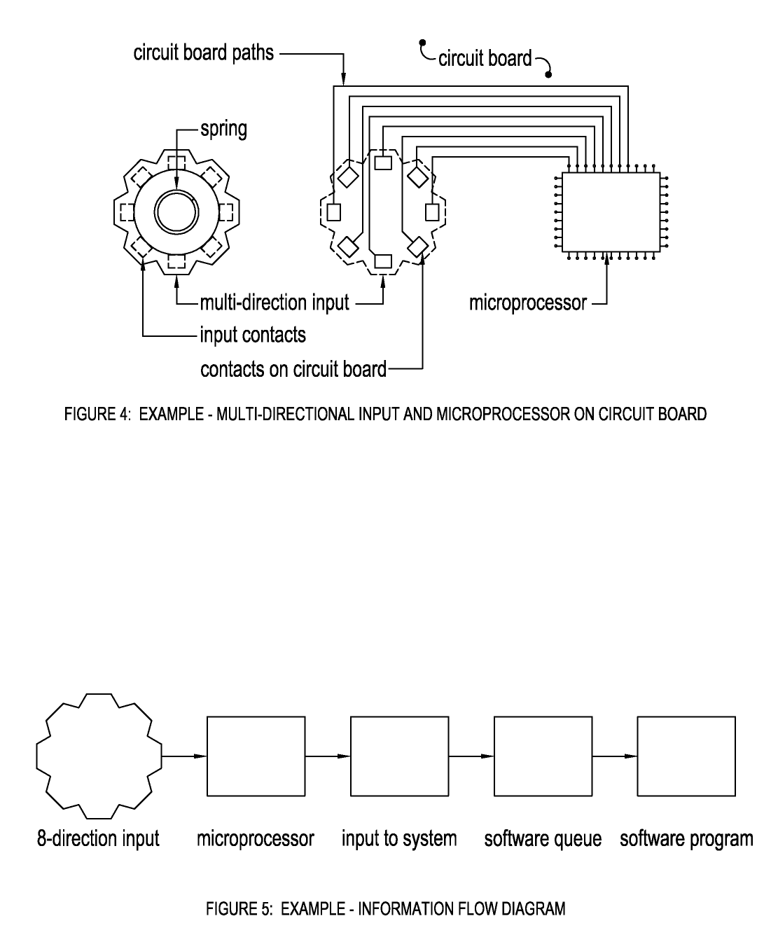

Two 8-direction inputs can be created using molded plastic, springs and contacts (see FIG. 4). A microprocessor polls the inputs to determine when the state of each contact changes. The microprocessor sends the change events to the connected system, using the appropriate protocol. The software in the system determines when the two 8-direction inputs are in non-neutral positions and looks up which character is assigned to those inputs and sends it to the destination or keyboard queue (see FIG. 5).

### DETAILED DESCRIPTION OF THE DRAWINGS

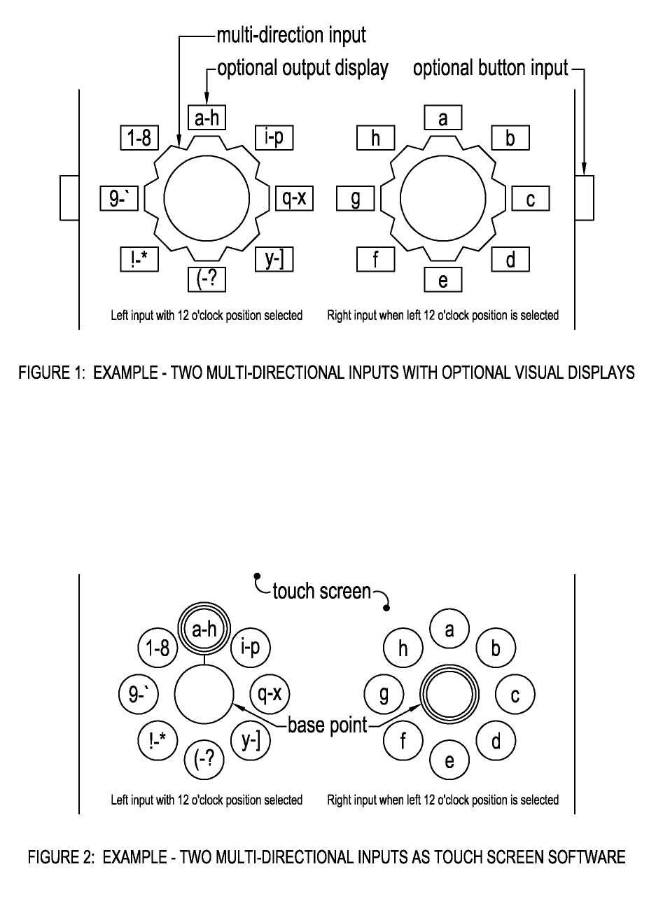

FIG. 1: EXAMPLE-Two hardware 8-direction inputs are shown. The left input is in the 12 o'clock position and the right input is neutral. The optional visual display screens around the left input show the range of characters that pressing that direction allows. With the left side in the 12 o'clock position the display screens around the right input show the individual characters that will be input for each direction. The optional buttons can increase the number of characters to input.

FIG. 2: EXAMPLE-A user has selected two base points on a touchscreen and moved the left input into the 12 o'clock position. The software shows the available range of characters for the left input and the directions around the right input show the individual characters now available to be entered. The software handles the directional inputs, the events, and the input to the program.

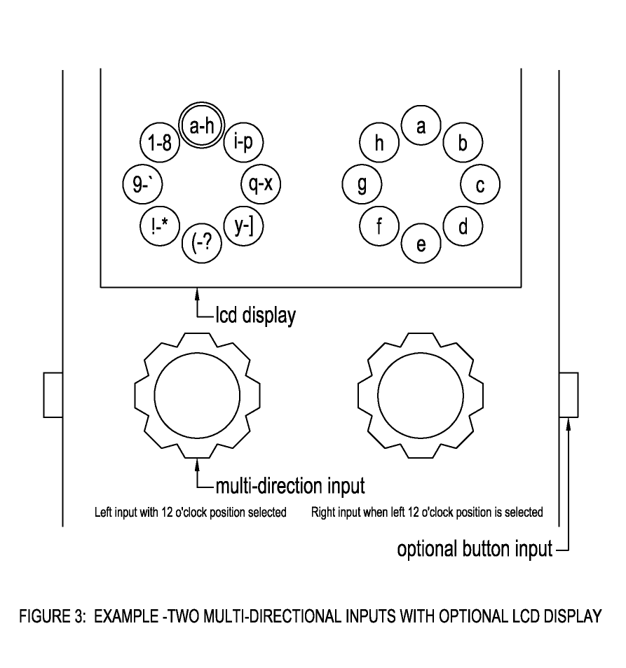

FIG. 3: EXAMPLE-Two hardware 8-direction inputs are shown. The left input is in the 12 o'clock position and the right input is neutral. The LCD display for the device shows the possible inputs for each 8-direction input. With the left side in the 12 o'clock position the display for the right input shows the individual characters that will be input for each direction. The optional buttons can increase the number of characters to input.

FIG. 4: EXAMPLE-A simple 8-direction input with contacts for each direction, each connected to voltage source. A spring will return the input to the neutral position. The circuit board shows the contacts each directional contact will hit connected (via circuit paths) to the level sensing inputs of the microprocessor.

FIG. 5: EXAMPLE-The diagram shows the flow of information from the 8-direction input contacts to the software running. The contacts' state is sensed by the microprocessor. The microprocessor outputs to the connected system, using the appropriate communication standard. The character is sent to the message queue and finally sent to the program.

1. A device or program implementing a user interface consisting of two multi-direction inputs to produce alphanumeric character input for devices in the manner of a keyboard.

2. The device or program of claim 1 can optionally include additional inputs as buttons, switches, tilt functions, etc. to increase the number of alphanumeric characters available for input or to act as a Shift, Ctrl, Alt, etc. function (in the manner of keyboard keys).

3. The device or program of claim 1 sends alphanumeric input for the connected device when both multi-directional inputs are put into non-neutral positions.

4. The device or program of claim 1 does not send input when one of the multi-direction inputs is in the neutral (center) position.

5. The device or program of claim 1 can be made with a multitude of existing hardware multi-direction devices, buttons, etc. or as software for existing devices with two multi-direction inputs, touch screens, or any device that can accept two multi-directional inputs.

6. The device or program of claim 1 can optionally have a mode where it retains the state of the first input (both directions) and accepts a second input (the inputs are in series) to enable the device to input a much larger set of characters.

7. The device or program of claim 1 can optionally include visual output around the multi-directional inputs or on an LCD display to show which characters will be input for each direction of the multi-directional inputs.

8. The device or program of claim 1 can optionally include outputs around the multi-directional inputs for braille display to indicate which characters will be input for each direction of the multi-directional inputs.

9. The optional displays of claims 7 and 8 show the user which alphanumeric characters are available for the associated directions. When one input's direction is selected the other input's displays show the individual characters that will be input when that direction is selected.
